(19) United States
(12) Patent Application Publication
(10) Pub. No.: US 2016/0338231 A1
(43) Pub. Date: Nov. 17, 2016

(54) COOLING SYSTEMS AND ASSOCIATED METHODS

(71) Applicant: Quantum Fuel Systems Technologies Worldwide, Inc., Lake Forest, CA (US)

(72) Inventors: Paul Prado, Lake Forrest, CA (US); Joseph Hudak, III, Long Beach, CA (US)

(73) Assignee: Quantum Fuel Systems Technologies Worldwide, Inc., Lake Forest, CA (US)

(21) Appl. No.: 15/154,305

(22) Filed: May 13, 2016

Related U.S. Application Data
(60) Provisional application No. 62/161,830, filed on May 14, 2015.

(51) Int. Cl. H05K 7/20; F28F 13/12; F28F 3/02; F28F 13/06; F28D 15/00; F28F 3/10

(52) U.S. Cl. CPC H05K 7/20927; F28D 15/00; F28F 3/10; F28F 3/022; F28F 13/06; F28F 13/12; F28F 2230/00; F28F 2250/08

(57) ABSTRACT

The present disclosure provides fluid management methods and systems for cooling heat dissipating surfaces resulting in improved power output. The present disclosure also provides for apparatuses used to perform the methods of the present disclosure including liquid cooling systems with liquid cooling wells adapted to engage with the heat dissipating surfaces, with the liquid cooling wells having surfaces comprising one or more flow-modification elements.

### CROSS REFERENCE TO RELATED APPLICATIONS

This application claims priority to U.S. Provisional Application 62/161,830, filed May 14, 2015, the contents of which is incorporated herein by reference in its entirety.

### TECHNICAL FIELD

This disclosure is in the field of cooling systems for electronics and associated methods. In particular, the disclosure relates to devices and methods for use in providing liquid cooling to power electronic components.

### BACKGROUND

Power electronics devices and systems are critical components for efficiently generating, transmitting, distributing, and converting electric power for various end uses, including hybrid and electric vehicles. Electronic components convert a portion of the power flowing through them into waste heat. Many components are temperature sensitive, with higher operating temperatures detrimentally affecting performance and reliability.

Thus, there is a need for systems and methods that can provide effective cooling to electronic components to remove waste heat. The disclosure is directed to these and other important needs.

### DISCLOSURE

The present disclosure provides aspects of cooling systems comprising a cooling plate comprising a liquid cooling well adapted to receive a heat dissipating surface of a module, a sealing region around the top edge of the liquid cooling well, wherein the sealing region is adapted to interface with a complementary mating region on the module in order to seal the liquid cooling well, one or more well inlets fluidly connected with the liquid cooling well, one or more well outlets fluidly connected with the liquid cooling well, and a return loop fluidly connecting the well outlets to the well inlets, the cooling system further comprising a cooling fluid disposed within the liquid cooling well and return loop, a means for motivating movement of the cooling fluid from the well inlets to the well outlets, and a means of reducing the temperature of the cooling fluid. In some implementations, the liquid cooling well further comprises surfaces comprising one or more flow-modification elements.

The present disclosure provides methods of cooling heat dissipating surfaces, wherein the methods comprise providing a cooling fluid within a liquid cooling well of a cooling plate, wherein the cooling plate comprises a liquid cooling well adapted to receive a heat dissipating surface of a module, a sealing region around the top edge of the liquid cooling well, wherein the sealing region is adapted to interface with a complementary mating region on the module in order to seal the liquid cooling well, one or more well inlets fluidly connected with the liquid cooling well, one or more well outlets fluidly connected with the liquid cooling well, and a return loop fluidly connecting the well outlets to the well inlets, the methods further comprising engaging the heat dissipating surface with the liquid cooling well such that the cooling fluid contacts the heat dissipating surface, engaging the module with a sealing region of the cooling plate such that the liquid cooling well is sealed with a pressure-tight seal, motivating the cooling fluid to move through the cooling well from one or more well inlets to one or more well outlets, motivating the cooling fluid through a return loop from the well outlets to the well inlets, passing the cooling fluid in the return loop through a means of reducing the temperature of the cooling fluid, and operating the module.

The present disclosure provides aspects of thermally managed power devices comprising a power module with a heat dissipating surface, a cooling plate engaged with the power module, wherein the cooling plate comprises a liquid cooling well adapted to receive the heat dissipating surface, a sealing region around the top edge of the liquid cooling well, wherein the sealing region is adapted to interface with a complementary mating region on the power module in order to seal the liquid cooling well, one or more well inlets fluidly connected with the liquid cooling well, one or more well outlets fluidly connected with the liquid cooling well, and a return loop fluidly connecting the well outlets to the well inlets, the devices further comprising a means for motivating movement of the cooling fluid from the well inlets to the well outlets, a means of reducing the temperature of the cooling fluid, a bus bar operatively connected to the power module and disposed on an opposing surface of the cooling plate from the module, and capacitors disposed on the bus bar on an opposing surface from the cooling plate.

The general description and the following detailed description are exemplary and explanatory only and are not restrictive of the disclosure, as defined in the appended claims. Other aspects of the present disclosure will be apparent to those skilled in the art in view of the detailed description of the disclosure as provided herein.

### BRIEF DESCRIPTION OF THE DRAWINGS

The summary, as well as the following detailed description, is further understood when read in conjunction with the appended drawings. For the purpose of illustrating the disclosure, there are shown in the drawings exemplary implementations of the disclosure; however, the disclosure is not limited to the specific methods, compositions, and devices disclosed. In addition, the drawings are not necessarily drawn to scale. The patent or application file contains at least one drawing executed in color. Copies of this patent or patent application publication with color drawing(s) will be provided by the Office upon request and payment of the necessary fee.

In the drawings:

FIG. 1 illustrates aspects of a cooling system according to the present disclosure;

FIG. 2 illustrates aspects of a cooling system according to the present disclosure;

FIG. 3 illustrates an assembly view of aspects of a power electronics system incorporating a cooling system of the present disclosure;

FIG. 4 illustrates a bottom view of a module heat dissipating surface;

FIG. 5 illustrates a side view of a module with a heat dissipating surface;

FIG. 6 illustrates aspects of a cooling system according to the present disclosure;

FIG. 7 illustrates aspects of a cooling system according to the present disclosure;

FIG. 8 illustrates aspects of a cooling system according to the present disclosure;

FIG. 9 illustrates aspects of a cooling system according to the present disclosure;

FIG. 10 illustrates aspects of a cooling system according to the present disclosure;

FIG. 11 illustrates aspects of a cooling system according to the present disclosure; and an Appendix. The Appendix includes details of the implementations of the cooling systems of FIGS. 10 and 11 (four pages of engineering schematics) and results of thermal performance modeling of an implementation (labeled “FIG. Appendix-2”) and a prior art system (labeled “FIG. Appendix-1”). Annotated versions of FIG. Appendix-1 and FIG. Appendix-1 are included to note particular temperature zones if the figures are presented in grayscale.

All reference numerals, designators, and call-outs in the figures and Appendix are hereby incorporated by this reference as fully set forth herein. The failure to number an element in a figure is not intended to waive any rights, and unnumbered references may also be identified by alpha characters in the figures and Appendix.

### FURTHER DISCLOSURE

The present disclosure may be understood more readily by reference to the following detailed description taken in connection with the accompanying figures and examples, which form a part of this disclosure. It is to be understood that this disclosure is not limited to the specific devices, methods, applications, conditions or parameters described and/or shown herein, and that the terminology used herein is for the purpose of describing particular exemplars by way of example only and is not intended to be limiting of the claimed disclosure. Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another exemplar includes from the one particular value and/or to the other particular value. Similarly, when values are expressed as approximations, by use of the antecedent “about,” it will be understood that the particular value forms another exemplar. All ranges are inclusive and combinable.

It is to be appreciated that certain features of the disclosure which are, for clarity, described herein in the context of separate exemplar, may also be provided in combination in a single exemplary implementation. Conversely, various features of the disclosure that are, for brevity, described in the context of a single exemplary implementation, may also be provided separately or in any subcombination. Further, reference to values stated in ranges include each and every value within that range.

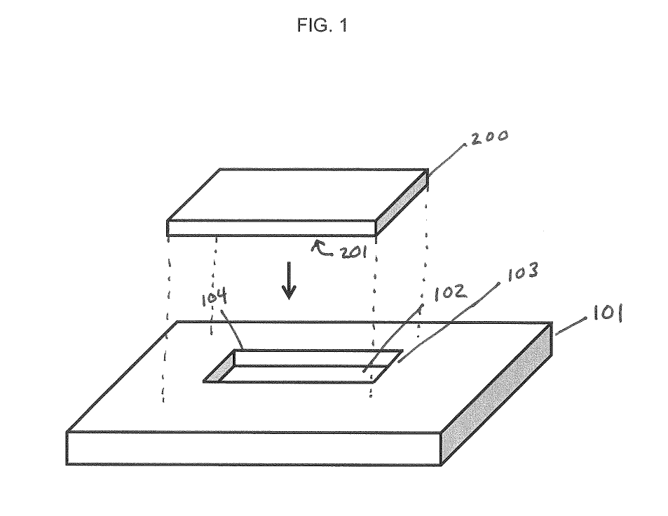

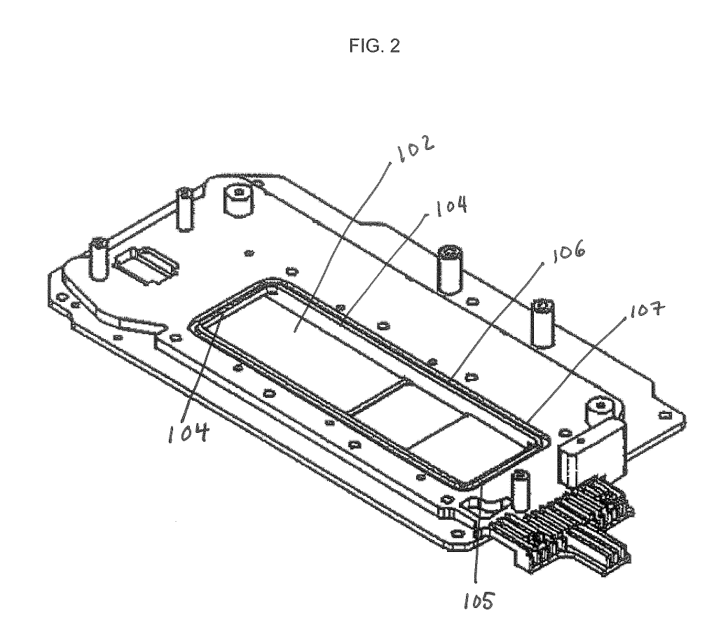

In one aspect, the present disclosure provides liquid cooling systems that are adapted to remove heat from a module. As depicted in non-limiting FIGS. 1 and 2, the liquid cooling systems may comprise a cooling plate 101 comprising a liquid cooling well 102 adapted to receive a heat dissipating surface 201 of a module 200 that can be engaged with the liquid cooling system. The liquid cooling well is surrounded by a sealing region 103 around the top edge 104 of the well. The sealing region 103 may be adapted to interface with a complementary mating region on the module 200 in order to seal the liquid cooling well. In some implementations, an O-ring 106, gasket, or other sealing means may be disposed in the sealing region in order to aid in the formation of a pressure-tight seal between the cooling plate and the module. In some implementations, a groove 107 to retain the O-ring can be provided in the sealing region or in the complementary mating region of the module. A cooling fluid is forced through the liquid cooling well with a pump or other suitable means of motivating fluid from one or more well inlets 104 to one or more well outlets 105. The pump or other suitable means of motivating fluid can be located within cooling plate 101 or can be a separate component connected via fluid conduits. When used herein when referring to the liquid cooling well, the term “length” refers to the dimension of the liquid cooling well between the well inlets and well outlets, along the general direction of cooling fluid flow through the well; the term “downstream” refers to a position or region within the liquid cooling well that is more proximate to the well outlets; the term “upstream” refers to a position or region within the liquid cooling well that is more proximate to the well inlets; the term “width” refers to the dimension of the well that is normal to the “length” and general flow direction; and the term “depth” refers to the distance between the heat dissipating surface of the module and an opposing surface of the cooling well in the direction normal to the length and width of the well. The cooling fluid flows through the liquid cooling well from one or more inlets to one or more outlets. While the cooling fluid passes through the liquid cooling well, the cooling fluid contacts the heat dissipating surface of the module and removes heat from the module. As a result, the cooling fluid generally increases in temperature between the one or more inlets and one or more outlets. After leaving the cooling well via the outlets, the cooling fluid may be carried to a means of reducing the temperature of the cooling fluid in a return loop between the outlets and the inlets. In some implementations, the means of reducing the temperature of the cooling fluid may comprise a radiator system for heat transfer to air. The means of reducing the temperature may be part of the cooling plate 101 or may be part of a separate component which is connected via fluid conduits.

Those of ordinary skill in the art will appreciate that a variety of fluids can be used as the cooling fluid in the systems disclosed herein. Any suitable fluid can be used for the various features described herein, and a skilled artisan will be able to select appropriate fluids based on various considerations, including the viscosity and thermal characteristics of the fluid, expected operating temperatures, and compatibility with the equipment and/or accessories with which they are intended to be used, among other considerations. Suitable cooling fluids can be water, another coolant fluid such as an antifreeze, an antifreeze-and-water blend, or an oil or a mixture of oils.

In some instances, the heat dissipating surface may comprise a surface with pin fins or other thermal management structures designed to remove heat from electronic components within the module. In other implementations, the heat dissipating surface may comprise the backside of a module with no additional thermal management structures thereon. In some implementations, the heat dissipating surface may comprise a surface of a power electronics module.

In exemplary implementations where the heat dissipating surface comprises an array of pin fins, the pin fin geometry and configuration can vary. Pin fins configurations can include louvered fins, wavy fins, straight fins, angled or slanted fins, or strip or lanced off-set fins. Fin geometry can be varied with respect to fin length, cross-section, and fin density across the heat dissipating surface to create non-linear arrays. In some implementations, the pin fin patterns can be metal-injection molded, or machined to create optimized fin patterns. In some implementations, the pin fins can be made from metal, metal-matrix composite material, or a combination thereof. Materials hereinafter discovered and/or developed that are determined to be suitable for use in the features and elements described herein would also be considered acceptable. The pin fin geometry can be designed to operate in conjunction with the liquid cooling well geometry such that the coolant can extract the maximum amount of heat from the heat dissipating surface in the flow path.

The heat dissipating surface of the module may not have uniform heat flux across its surface. In some implementations, one or more internal electronic components of the module will produce waste heat that creates one or more “hot spot” locations on the heat dissipating surface. “Hot spot” locations are regions of greater heat flux on the heat dissipating surface 201 of the module 200.

In one aspect, the present disclosure provides liquid cooling systems that are adapted to effectively remove heat from a plurality of “hot spot” locations across the heat dissipating surface. In prior art systems, the cooling fluid flows through a cooling well with substantially planar internal surfaces that is adapted to enclose a pin fin array with minimal excess volume such that cooling fluid cannot bypass the pin fin structures. An example of such a system is depicted in FIG. 6. The prior art systems typically result in a temperature gradient across the cooling well such that “hot spot” locations nearer to the outlets are exposed to higher temperature cooling fluid volume than “hot spot” locations nearer to the inlets. In operation, such prior art systems result in temperature differences across the corresponding internal components within the module. In some exemplary implementations, the present disclosure provides liquid cooling wells with surfaces comprising flow-modification elements to deliver more uniform temperature cooling fluid to the “hot spot” locations across the heat dissipating surface. In some implementations, one or more regions of the cooling well may be larger than the volume of the pin fin array depth, width, or both such that the cooling fluid can bypass the pin fin structure in some regions.

In some exemplary implementations, the flow-modification elements comprise one or more steps in the surfaces of the liquid cooling well. The liquid cooling wells may comprise a plurality of regions separated by one or more steps, which are transitions between well regions of different depths. A rising step between two regions, where the depth downstream of the step is less than the depth upstream of the step, will expose the heat dissipating surface adjacent to the well region immediately downstream of the step to cooling fluid that has had less exposure to the heat dissipation in the section of the liquid cooling well upstream of the step. In some implementations, steps are positioned in positions upstream of “hot spot” locations on the heat dissipating surface. In this manner, each step provides for a reduction in the temperature of the cooling fluid interacting with the heat dissipating surface downstream of the step in comparison with the heat dissipating surface upstream of the step. During operation of the liquid cooling system this causes each “hot spot” to be exposed to cooling fluid at similar temperatures across the entirety of the length of the cooling well. Steps can be disposed across the entirety of the width of the well, across substantially the entirety of the width of the well, or across one or more portions of the width of the well. Steps can be rising steps that decrease the depth of the well or lowering steps that increase the depth of the well. Steps can be perpendicular to the bottom of the well, or can be formed at other angles.

In some exemplary implementations, the flow-modification elements comprise one or more surface features on the surfaces of the liquid cooling well. The surface features can comprise ridges, divots, bumps, ramps, grooves, channels, troughs, undulations, knurling, friction-enhancing texturing, or a combination or sub-combination thereof. In some exemplary implementations the surface features are positioned such that a volume of cooling fluid that has been exposed to less heat flux from the heat dissipating surface, and accordingly has a lower temperature in comparison to other volumes of cooling fluid in the well, is directed to flow towards a “hot spot” location downstream of the surface feature. During operation of the liquid cooling system this causes each “hot spot” to be exposed to cooling fluid at similar temperatures across the entirety of the length of the cooling well. This leads to more even heat removal across the length of the cooling well.

In some exemplary implementations, the depth of the cooling well may exceed the length of some or all of the pin fin array of the module. The depth of the cooling well may vary across the length and width of the well. In some implementations, the depth of the cooling well generally decreases from the well inlets to the well outlets, with flow-modification elements disposed at various positions that locally increase or decrease the depth of the well in those various positions.

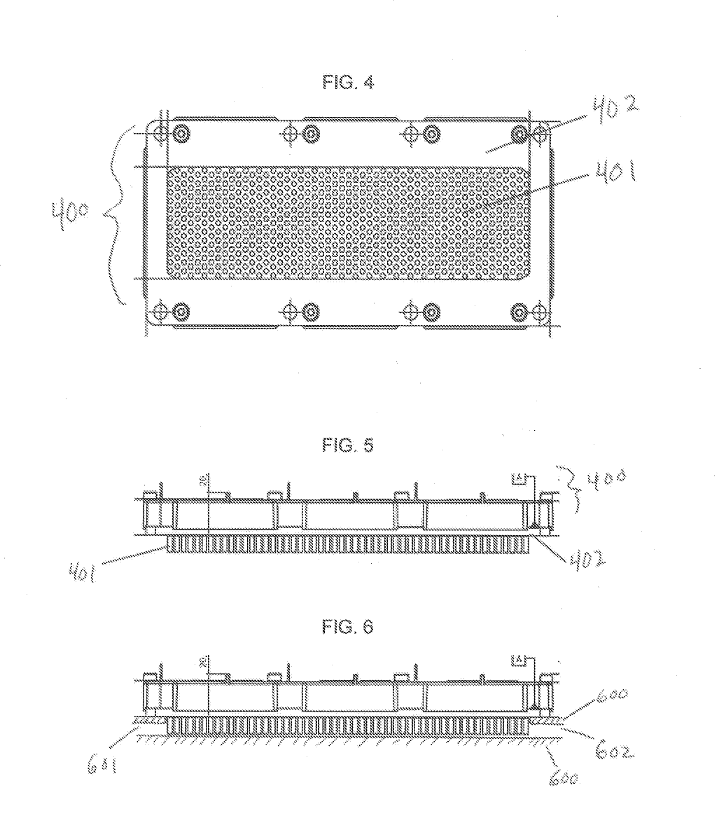

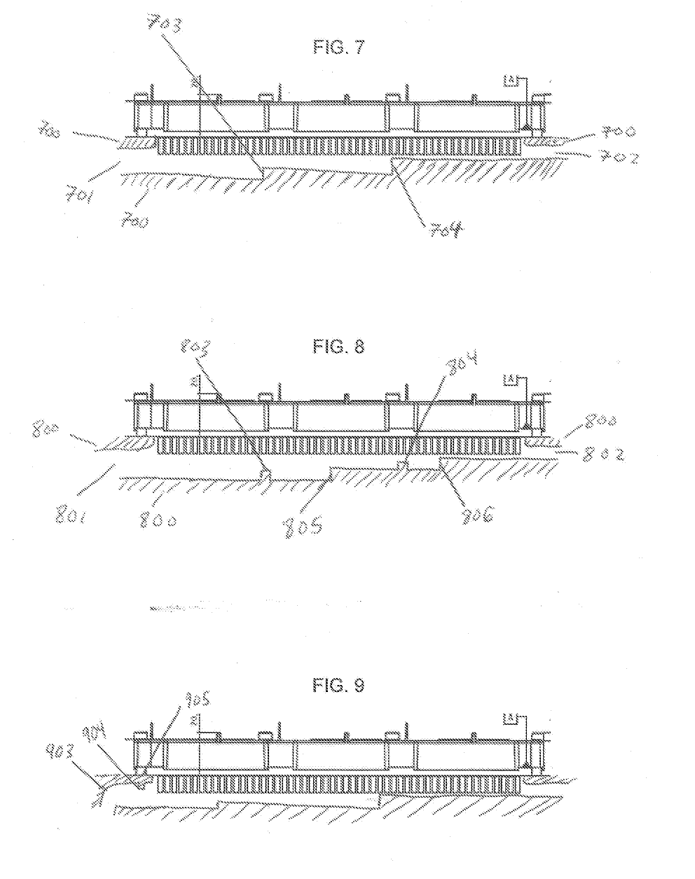

Some exemplary implementations of cooling wells are depicted in FIGS. 6-9, which depict cross-section views of different cooling plates integrated with an exemplary power module with thermal pin fins. All aspects of the liquid cooling systems are not shown in these figures, which merely depict some aspects of the cooling wells of the disclosure. FIG. 4 depicts a bottom view of an exemplary power module 400, with a pin fin array 401 visible in a central portion of the bottom surface 402. FIG. 5 depicts a side cross-section view of the exemplary power module 400, with pin fin array 401 protruding from the bottom surface 402. FIG. 6 depicts a typical design of a cold plate system 600, which comprises a uniform cooling well geometry with depth substantially equal to the pin fin length and without flow-modification elements. Cold plate system 600 may comprise a plurality of component parts that are connected together to form the operational system. This typical design results in a temperature gradient in the cooling fluid between the inlet 601 and the outlet 602 during operation, with hotter cooling fluid nearest the outlet, which leads to uneven cooling of the internal elements of the power module. FIG. 7 depicts aspects of one exemplary implementation of a cooling well of the present disclosure in a cold plate 700. Cold plate system 700 may comprise a plurality of component parts that are connected together to form the operational system. In this implementation, the cooling well depth decreases between inlet 701 and outlet 702 through the use of flow-modification elements of steps 703 and 704. The initial depth of the cooling well, nearest the inlet, is greater than the length of the pin fins. Different amounts of steps can be used in other implementations as desired to create even cooling for modules with varying thermal characteristics. FIG. 8 depicts aspects of an exemplary implementation of a cooling well of the present disclosure, with inlet 801 and outlet 802. This implementation incorporates flow-modification elements of ridges 803 and 804, and steps 805 and 806, to modify the flow path and vary the depth of the cooling well at different locations along the length of the cooling well. FIG. 9 depicts aspects of an exemplary implementation of a cooling well of the present disclosure, with optional aspects of the cooling plate upstream of the cooling well illustrated. These upstream aspects may comprise a flow-evening radius 903 and a flow-modification element 904 disposed in the inlet flow channel underneath the sealing region 905, which serve to even out the flow across the depth of the cooling well prior to contact with the pin fins and any flow-modification elements. Although flow-evening radius 903 is depicted in FIG. 9 with the flow channel inlet approaching the cooling well from underneath the cooling well, in other implementations the inlet could approach from the side, in the same horizontal plane as the cooling well. In such implementations, a flow-evening radius 903 may be similarly employed. Although the pin fin arrays depicted in FIGS. 4-9 are uniform, non-linear pin fin arrays could be designed to further enhance the cooling performance of the cooling system as applied to particular modules.

The present disclosure also provides devices comprising a cooling plate of any implementation described herein and a module operatively connected to the cooling plate. In some implementations, the devices further comprise a bus bar operatively connected to the module and disposed on an opposing surface of the cooling plate from the module, and in further implementations the devices further comprise capacitors disposed on the bus bar on an opposing surface from the cooling plate.

The present disclosure provides methods of cooling heat dissipating surfaces. The methods comprise providing a cooling fluid within a liquid cooling well of a cooling plate. In some implementations, the methods further comprise engaging a heat dissipating surface with the liquid cooling well such that the cooling fluid contacts the heat dissipating surface. In further implementations, the methods further comprise motivating the cooling fluid to move through the cooling well from one or more well inlets to one or more well outlets. In some implementations, the methods further comprise motivating the cooling fluid through a return loop from the well outlets to the well inlets. In some implementations the motivating of the cooling fluid is achieved through the use of a pump. In some implementations, the methods further comprise passing the cooling fluid in the return loop through a means of reducing the temperature of the cooling fluid. In further implementations, the means for reducing the temperature of the cooling fluid comprises a radiator system. In exemplary implementations, the liquid cooling well comprises one or more flow-modification elements as described elsewhere herein. In some implementations, the one or more flow-modification elements are configured to provide substantially uniform temperature cooling fluid across the length of the cooling well despite uneven heat flux regions across the heat dissipating surface.

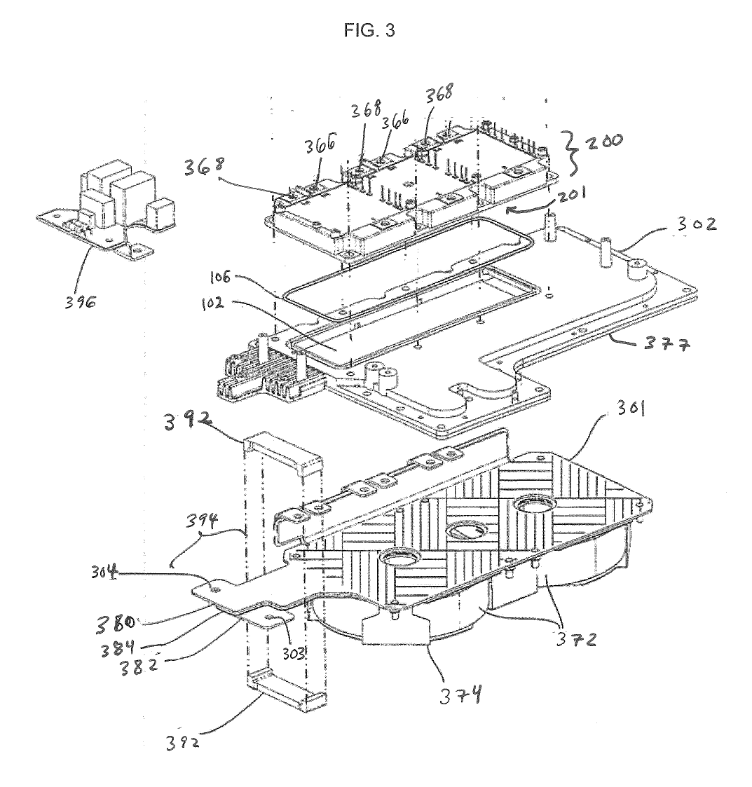

A power electronics assembly suitable for use in hybrid or electric vehicles was implemented with features of the present disclosure. The system described in the assignee's U.S. patent application Ser. No. 13/664,774 (published as pre-grant publication US 2013/0187453 A1), the entirety of which is incorporated herein for all purposes, was modified. An IGBT module, Infineon® model FS800R07A2E3, with a pin fin array as a heat dissipating surface, was incorporated into a power electronics assembly for engagement with a liquid cooling well. FIG. 3 depicts an exploded view of the assembly. As described more fully in U.S. patent application Ser. No. 13/664,774, the assembly includes IGBT module 200, with heat dissipating surface 201 (not visible) with a pin fin array, an O-ring 106, a cooling plate 302 with cooling well 102, a bus bar 301 with “fishtail” 394, tie points 303 (positive) and 304 (negative) that are connected to terminals 368 and 368 of the IGBT module, capacitors 372, adaptor bracket 374, positive conductor 382, negative conductor 280, separator 384, filter subassembly 392, X/Y capacitor assembly 396, and electrically isolating and thermally conductive pad 377.

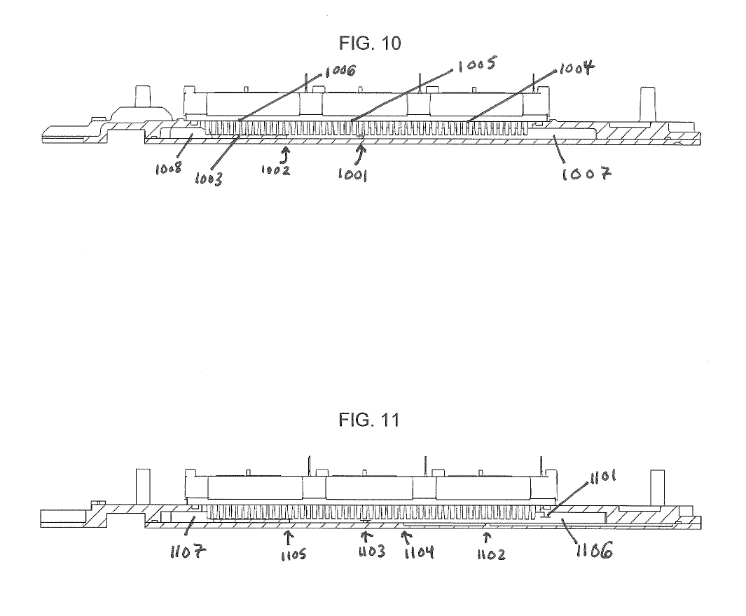

The heat dissipating surface 201 of the IGBT module is depicted in FIG. 4. Power electronics systems incorporating the IGBT module were assembled. One system incorporated a typical liquid cooling well with a uniform surface design, while the other systems incorporated liquid cooling wells with different depths and flow-modification features along the bottom surfaces of the wells. A representative cross-section of the typical uniform surface design is depicted in FIG. 6, while representative cross-sections of the alternative cooling well designs are depicted in FIGS. 10 and 11. The steps and ridge features were positioned upstream from approximate “hot spot” locations 1004, 1005, and 1006 corresponding to the position of IGBTs and other waste-heat-producing components within the module, as shown in FIG. 10 (“hot spot” locations are not shown, but are also present in the same approximate positions in FIG. 11). In the implementation depicted in FIG. 10, the cooling well with inlet 1007 and outlet 1008 includes a ridge 1001 and step 1002 that leads to a region 1003 of the cooling well with a decreased depth relative to the regions upstream thereof. In the implementation in FIG. 11, the cooling well includes a flow-evening feature 1101, ridges 1102 and 1103, and steps 1104 and 1105 that lead to decreases in depth of the well between the inlet 1106 and outlet 1107. The implementations in FIGS. 10 and 11 provide and have more even temperature of the cooling fluid, and pin fins, across the length of the cooling well during operation. This reduced temperature differences between the internal IGBTs of the module, which in turn improved performance of the module. The typical uniform surface design, similar to the system depicted in FIG. 6, results in a temperature difference between the coldest and hottest IGBT dies of approximately 11 degrees. The implementations in FIGS. 10 and 11 resulted in a temperature difference between the coldest and hottest IGBT dies of approximately 3.3 degrees. The tighter temperature differential resulted in increased power output, with the implementation of the present disclosure resulting in power output of approximately 150 kW, while the typical cold plate design was limited to approximately 120 kW which corresponds to an output of approximately 125% the output of typical designs. Further details of the implementations of FIGS. 10 and 11 are provided in the Appendix filed concurrently herewith. Some portions of the Appendix were a color image. They are also shown with interlineations in outline form to help understand what has been converted into grey scale.

Those of ordinary skill in the art will appreciate that a variety of materials can be used in the manufacturing of the components in the devices and systems disclosed herein. Any suitable structure and/or material can be used for the various features described herein, and a skilled artisan will be able to select an appropriate structures and materials based on various considerations, including the intended use of the systems disclosed herein, the intended arena within which they will be used, and the equipment and/or accessories with which they are intended to be used, among other considerations. Conventional polymeric, metal-polymer composites, metal-matrix composites, ceramics, and metal materials are suitable for use in the various components. Materials hereinafter discovered and/or developed that are determined to be suitable for use in the features and elements described herein would also be considered acceptable.

When ranges are used herein for physical properties, such as molecular weight, or chemical properties, such as chemical formulae, all combinations, and subcombinations of ranges for specific exemplar therein are intended to be included.

The disclosures of each patent, patent application, and publication cited or described in this document are hereby incorporated herein by reference, in its entirety.

Those of ordinary skill in the art will appreciate that numerous changes and modifications can be made to the exemplars of the disclosure and that such changes and modifications can be made without departing from the spirit of the disclosure. It is, therefore, intended that the appended claims cover all such equivalent variations as fall within the true spirit and scope of the disclosure.

What is claimed:

1. A cooling system comprising:
a cooling plate (101) comprising:
a liquid cooling well (102) adapted to receive a heat dissipating surface (201) of a module (200);
a sealing region (103) around the top edge (104) of the liquid cooling well (102), wherein the sealing region (103) is adapted to interface with a complementary mating region on the module (200) in order to seal the liquid cooling well;
one or more well inlets (104) fluidly connected with the liquid cooling well (102);
one or more well outlets (105) fluidly connected with the liquid cooling well (102); and, a return loop fluidly connecting the well outlets (105) to the well inlets (104);
a cooling fluid disposed within the liquid cooling well (102) and return loop;
a means for motivating movement of the cooling fluid from the well inlets (104) to the well outlets (105); and,
a fluid cooling means including at least heat dissipation pin fins to reduce the temperature of the cooling fluid.

2. The cooling system according to claim 1, wherein the liquid cooling well further comprises surfaces comprising one or more flow-modification elements.

3. The cooling system according to claim 2, wherein the one or more flow-modification elements comprise steps on one or more surfaces of the liquid cooling well, surface features on one or more surfaces of the liquid cooling well, or a combination thereof.

4. The cooling system according to claim 3, wherein the one or more flow-modification elements comprise steps on one or more surfaces of the liquid cooling well.

5. The cooling system according to claim 3, wherein the one or more flow-modification elements comprise ridges, divots, bumps, ramps, grooves, channels, troughs, undulations, knurling, friction-enhancing texturing, or a combination or sub-combination thereof on one or more surfaces of the liquid cooling well.

6. The cooling system according to claim 1, wherein the cooling plate further comprises flow-evening elements upstream from the cooling well.

7. The cooling system according to claim 6, wherein the flow-evening elements comprise a flow-evening radius, a flow-modification element, or a combination thereof disposed within the one or more well inlets.

8. The cooling system according to claim 2, wherein each of the one or more flow-modification elements is disposed immediately upstream of a region of greater heat flux on the heat dissipating surface 201 of the module 200.

9. The cooling system according to claim 1, wherein the heat dissipating surface comprises a pin fin array and one or more regions of the cooling well is larger than the volume of the pin fin array depth, width, or both such that the cooling fluid bypasses the pin fin structure in some regions.

10. A method of cooling a heat dissipating surface, the method comprising:
providing a cooling fluid within a liquid cooling well of a cooling plate, the cooling plate comprising:
a liquid cooling well 102 adapted to receive a heat dissipating surface 201 of a module 200,
a sealing region 103 around the top edge 104 of the liquid cooling well 102, wherein the sealing region 103 is adapted to interface with a complementary mating region on the module 200 in order to seal the liquid cooling well,
one or more well inlets 104 fluidly connected with the liquid cooling well 102,
one or more well outlets 105 fluidly connected with the liquid cooling well 102, and,
a return loop fluidly connecting the well outlets 105 to the well inlets 104;
engaging the heat dissipating surface 201 with the liquid cooling well such that the cooling fluid contacts the heat dissipating surface;
engaging the module 200 with a sealing region of the cooling plate such that the liquid cooling well is sealed with a pressure-tight seal;
motivating the cooling fluid to move through the cooling well from one or more well inlets to one or more well outlets;
motivating the cooling fluid through a return loop from the well outlets to the well inlets;
passing the cooling fluid in the return loop through a means of reducing the temperature of the cooling fluid; and,
operating the module 200.

11. The method of cooling a heat dissipating surface according to claim 10, wherein the liquid cooling well further comprises surfaces comprising one or more flow-modification elements.

12. The method of cooling a heat dissipating surface according to claim 11, wherein the one or more flow-modification elements are configured to provide substantially uniform temperature cooling fluid across the length of the cooling well in the presence of uneven heat flux regions across the heat dissipating surface.

13. The method of cooling a heat dissipating surface according to claim 10, wherein the heat dissipating surface 201 comprises one or more thermal management structures.

14. The method of cooling a heat dissipating surface according to claim 10, wherein the heat dissipating surface 201 comprises the backside of the module with no additional thermal management structures thereon.

15. The method of cooling a heat dissipating surface according to claim 10, wherein the heat dissipating surface 201 comprises a surface of a power electronics module.

16. The method of cooling a heat dissipating surface according to claim 13, wherein the one or more pin fin elements comprise a non-linear pin fin array.

17. A thermally managed power device comprising:
a power module with a heat dissipating surface;
a cooling plate engaged with the power module, the cooling plate comprising:
a liquid cooling well 102 having one or more flow-modification elements adapted to receive the heat dissipating surface,
a sealing region 103 around the top edge 104 of the liquid cooling well 102, wherein the sealing region 103 is adapted to interface with a complementary mating region on the power module in order to seal the liquid cooling well,
one or more well inlets 104 fluidly connected with the liquid cooling well 102,
one or more well outlets 105 fluidly connected with the liquid cooling well 102, and\
a return loop fluidly connecting the well outlets 105 to the well inlets 104;
a cooling fluid disposed within the liquid cooling well and return loop;
a means for motivating movement of the cooling fluid from the well inlets to the well outlets;
a means of reducing the temperature of the cooling fluid;
a bus bar operatively connected to the power module and disposed on an opposing surface of the cooling plate from the module; and,
capacitors disposed on the bus bar on an opposing surface from the cooling plate.

18. The thermally managed power device according to claim 17, wherein the one or more flow-modification elements comprise steps on one or more surfaces of the liquid cooling well, surface features on one or more surfaces of the liquid cooling well, or a combination thereof.

19. The thermally managed power device according to claim 18, wherein the one or more flow-modification elements comprise steps on one or more surfaces of the liquid cooling well.

20. The thermally managed power device according to claim 18, wherein the one or more flow-modification elements comprise ridges, divots, bumps, ramps, grooves, channels, troughs, undulations, knurling, friction-enhancing texturing, or a combination or sub-combination thereof on one or more surfaces of the liquid cooling well.
